(19) United States
(12) Patent Application Publication
(10) Pub. No.: US 2021/0319982 A1
(43) Pub. Date: Oct. 14, 2021

(54) GAS SUPPLY UNIT AND SUBSTRATE PROCESSING APPARATUS INCLUDING THE SAME

(71) Applicant: ASM IP Holding B.V., Almere (NL)

(72) Inventors: JaeHyun Kim, Hwaseong-si (KR); DaeYoun Kim, Seo-gu (KR); JeongHo Lee, Seoul (KR); HyunSoo Jang, Osan-si (KR); YonJong Jeon, Yongin-si (KR)

(21) Appl. No.: 17/224,779

(22) Filed: Apr. 7, 2021

Related U.S. Application Data
(60) Provisional application No. 63/008,536, filed on Apr. 10, 2020.

(51) Int. Cl. H01J 37/32; C23C 16/455; C23C 16/52

(52) U.S. Cl. CPC H01J 37/32449; C23C 16/45536; H01L 21/67017; C23C 16/45565; C23C 16/52

(57) ABSTRACT

A substrate processing apparatus capable of preventing power dissipation and achieving high process reproducibility includes a partition and a processing unit below the partition, wherein the processing unit includes a conductive body and at least one conductive protrusion integrally formed with the conductive body.

### CROSS-REFERENCE TO RELATED APPLICATIONS

This application claims the benefit of and priority to U.S. Provisional Application No. 63/008,536, filed on Apr. 10, 2020 in the United States Patent and Trademark Office, the disclosure of which is incorporated herein in its entirety by reference.

### BACKGROUND

### 1. Field

One or more embodiments relate to a gas supply unit and a substrate processing apparatus including the same, and more particularly, to a gas supply unit for processing a substrate and a substrate processing apparatus including the gas supply unit.

### 2. Description of the Related Art

When processing a substrate at a high temperature in a semiconductor or a display manufacturing apparatus, the process may need to be performed in a high temperature atmosphere. In this case, due to the high temperature atmosphere, deformation of a reactor may occur. Due to the deformation of the reactor, power loss (especially, RF power in plasma processing), etc. may occur and process reproducibility may deteriorate.

The problem of deformation of the reactor in a high temperature atmosphere is also mentioned in Korean Patent Publication No. 10-2011-0058534. In more detail, it is mentioned below that a gas injection plate is manufactured to a large size with an increase in a size of a substrate, and thickness uniformity of a deposited thin film is deteriorated due to increased deformation by heat.

### SUMMARY

One or more embodiments include a gas supply unit and a substrate processing apparatus including the same, which may prevent reactor deformation in a high-temperature process as described above and the resulting power loss and decrease in process reproducibility.

Additional aspects will be set forth in part in the description which follows and, in part, will be apparent from the description, or may be learned by practice of the presented embodiments of the disclosure.

According to one or more embodiments, a substrate processing apparatus includes a partition and a processing unit below the partition, wherein the processing unit includes a conductive body and at least one conductive protrusion formed integrally with the conductive body.

According to an example of the substrate processing apparatus, the substrate processing apparatus may further include a metal conductive joint between the conductive body and the conductive protrusion, wherein the conductive body, the conductive protrusion, and the metal conductive joint may be integrally formed with one another.

According to another example of the substrate processing apparatus, the metal conductive joint may have a curvature.

According to another example of the substrate processing apparatus, the metal conductive joint may have a concave shape.

According to another example of the substrate processing apparatus, the substrate processing apparatus may further include a weld joint between the conductive body and the conductive protrusion.

According to another example of the substrate processing apparatus, the weld joint may include a fillet weld.

According to another example of the substrate processing apparatus, the fillet weld may have a concave shape.

According to another example of the substrate processing apparatus, at least one of the conductive body, the conductive protrusion, and the weld joint may further include a heat-affected portion, and the heat-affected portion may have different properties from the conductive body, the conductive protrusion, and the weld joint.

According to another example of the substrate processing apparatus, the conductive body may include a plurality of first coupling holes formed along a first circumference apart from the center of the conductive body and having a first radius, and a plurality of second coupling holes formed along a second circumference apart from the center of the conductive body and having a second radius greater than the first radius.

According to another example of the substrate processing apparatus, the conductive body and the conductive protrusion may be fixed to the partition through a first coupling unit arranged in a first coupling hole, and the conductive body and the conductive protrusion may be further fixed to the partition through a second coupling unit arranged in a second coupling hole.

According to another example of the substrate processing apparatus, the at least one conductive protrusion may be on the second circumference.

According to another example of the substrate processing apparatus, the conductive body may include a first surface in which a plurality of injection holes are formed and a second surface opposite to the first surface, and the conductive protrusion may protrude from the second surface.

According to another example of the substrate processing apparatus, the conductive protrusion may include an end portion extending from the second surface to pass through the partition.

According to another example of the substrate processing apparatus, the substrate processing apparatus may further include a power supply portion, and the end portion of the conductive protrusion may be electrically connected to the power supply portion.

According to another example of the substrate processing apparatus, the substrate processing apparatus may further include a heating unit arranged to contact the partition, a first thermocouple configured to measure the temperature of a first portion of the heating unit, and a second thermocouple configured to measure the temperature of a second portion of the heating unit.

According to another example of the substrate processing apparatus, the first thermocouple and the second thermocouple may be arranged symmetrically with respect to the center of the heating unit.

According to one or more embodiments, a gas supply unit may include a conductive body, a conductive protrusion protruding from the conductive body, and a concave fillet between the conductive body and the conductive protrusion.

According to an example of the gas supply unit, the conductive body, the conductive protrusion, and the concave fillet may be integrally formed with each other by metal milling.

According to another example of the gas supply unit, the conductive body, the conductive protrusion, and the concave fillet may be integrally formed with each other by metal joining.

According to one or more embodiments, a substrate processing apparatus may include a partition, a heating unit in contact with the partition, a plurality of thermocouples configured to measure the temperature of the heating unit, a processing unit having a conductive body and at least one conductive protrusion integrally formed with the conductive body, a plurality of first coupling units configured to fix the processing unit to the partition, and a plurality of second coupling units configured to fix the processing unit to the partition, wherein the first coupling unit is arranged along a first circumference, and the second coupling unit is arranged along a second circumference having a greater diameter than that of the first circumference, and a fixing force of the processing unit to the partition generated by the first coupling unit arranged along the first circumference may be increased by the second coupling unit arranged along the second circumference.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view of a cross-section of a substrate processing apparatus according to embodiments of the inventive concept;

FIG. 2 is a view of a flow of a reaction gas (and residual gas) in a substrate processing apparatus according to embodiments of the inventive concept;

FIG. 3 is a cross-sectional view of a substrate processing apparatus according to embodiments of the inventive concept as viewed from another section;

FIG. 4 is a view of a processing unit included in a substrate processing apparatus according to embodiments of the inventive concept;

FIG. 5 is a cross-sectional view of the processing unit of FIG. 4, taken along line X-X′;

FIG. 6 is a partial view of a processing unit included in a substrate processing apparatus according to embodiments of the inventive concept;

FIG. 7 is a view showing an example wherein a gas curtain, which is a conductive body of a processing unit, and an RF rod, which is a conductive protrusion, are not integrated with each other and are mechanically coupled as separate components according to embodiments of the inventive concept;

FIGS. 8A and 8B are views illustrating deformation of a gas curtain at a high temperature of 300° C. or more according to embodiments of the inventive concept;

FIG. 9 is a view illustrating a state in which a sealing device such as an O-ring is corroded due to deformation of a processing unit according to embodiments of the inventive concept;

FIGS. 10A and 10B are views of a substrate processing apparatus according to embodiments of the inventive concept;

FIGS. 11A and 11B are views of a degree of deformation and process results of a reactor operating at a high temperature in a substrate processing apparatus according to embodiments of the inventive concept;

FIG. 12 is a view illustrating process results obtained by using a processing apparatus using a separate & inserted RF rod and a processing apparatus in which an RF rod and a gas curtain according to the disclosure are integrated, according to embodiments of the inventive concept;

FIG. 13 is a view of a wall heater on a partition and a thermocouple (TC) measuring temperature according to embodiments of the inventive concept;

FIG. 14 is a view illustrating process results when a dual thermocouple is applied according to embodiments of the inventive concept; and

FIG. 15 is a view of a substrate processing apparatus according to embodiments of the inventive concept.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, operations, members, components, and/or groups thereof, but do not preclude the presence or addition of one or more other features, integers, steps, operations, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

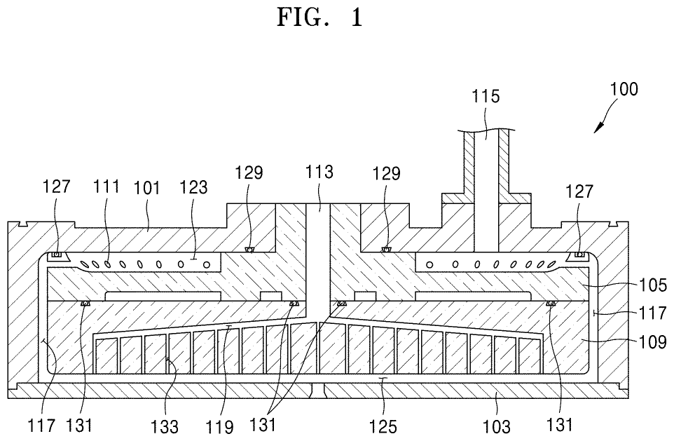

First, referring to FIG. 1, a substrate processing apparatus according to embodiments of the inventive concept will be described. FIG. 1 is a view showing a cross-section of a substrate processing apparatus 100 according to embodiments of the inventive concept.

Referring to FIG. 1, in the substrate processing apparatus 100, a partition 101 may contact a substrate support plate 103. In more detail, a reaction space may be formed when a lower surface of the partition 101 contacts the substrate support plate 103 serving as a lower electrode.

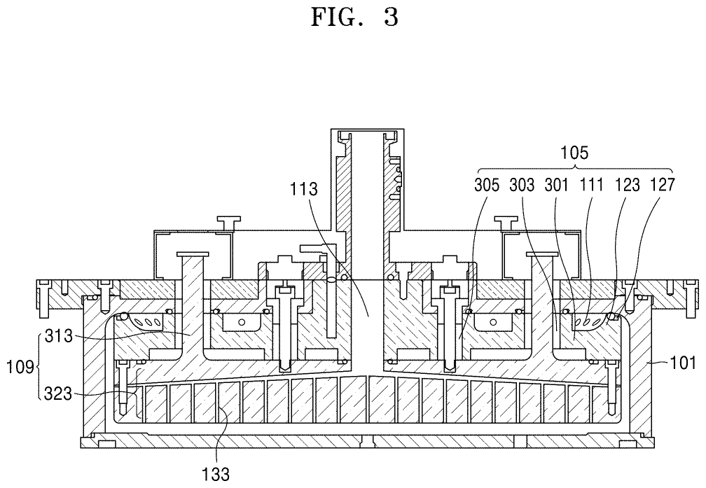

In other words, the substrate support plate 103 may be configured to face-seal with the partition 101, and a reaction space 125 may be formed between the partition 101 and the substrate support plate 103 by the face sealing. In addition, a gas exhaust path 117 may be formed, by the face sealing, between a gas flow control unit 105 and a partition and between a conductive body 323 (of FIG. 3) of the processing unit 109 and a partition 101.

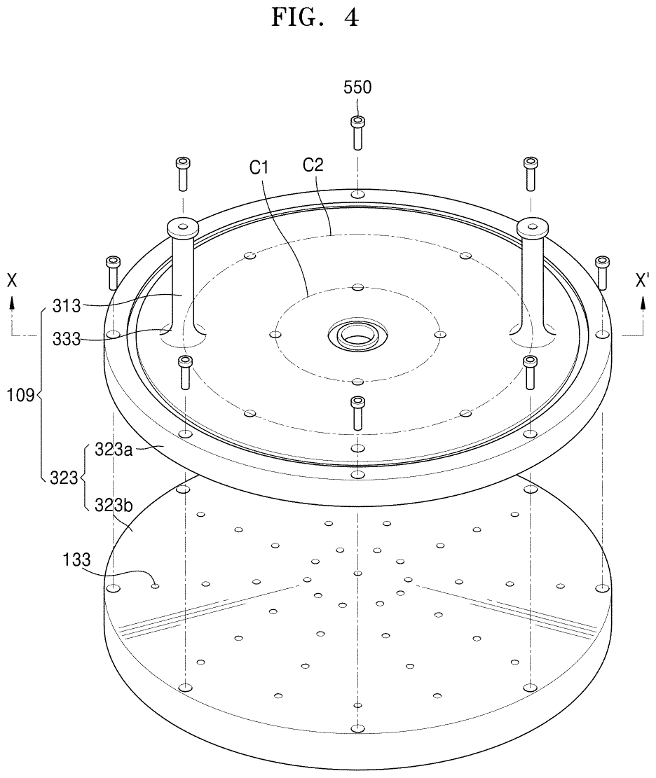

The gas flow control unit 105 and the processing unit 109 may be disposed between the partition 101 and the substrate support plate 103. The gas flow control unit 105 and the processing unit 109 may be integrally formed or may be configured separately. In a separate structure, the gas flow control unit 105 may be stacked over the conductive body 323 of the processing unit 109. Optionally, the conductive body 323 of the processing unit 109 (of FIG. 3) may also be of a separate type, in which case the processing unit 109 may include a gas injection portion having a plurality of through holes and a gas channel stacked over the gas injection portion (see FIGS. 3 and 4).

The gas flow control unit 105 may include a plate and a side wall 123 protruding from the plate. A plurality of holes 111 penetrating the side wall 123 may be formed in the side wall 123.

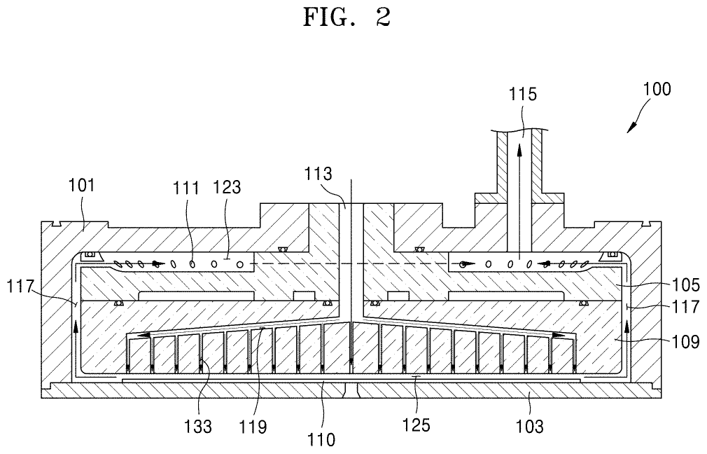

Grooves 127, 129, and 131 for accommodating a sealing member such as an O-ring may be formed between the partition 101 and the gas flow control unit 105 and between the gas flow control unit 105 and the processing unit 109. By the sealing member, an external gas may be prevented from entering the reaction space 125. In addition, by the sealing member, a reaction gas in the reaction space 125 may exit along a designated path (i.e., the gas exhaust path 117 and a gas outlet 115, see FIG. 2). Therefore, the outflow of the reaction gas into a region other than the designated path may be prevented.

The processing unit 109 may be used as an electrode in a plasma process such as a capacitively coupled plasma (CCP) method. In this case, the processing unit 109 may include a metal material such as aluminum (Al). In the CCP method, the substrate support plate 103 may also be used as an electrode, and as a result, capacitive coupling may be achieved by the processing unit 109 serving as a first electrode and the substrate support plate 103 serving as a second electrode.

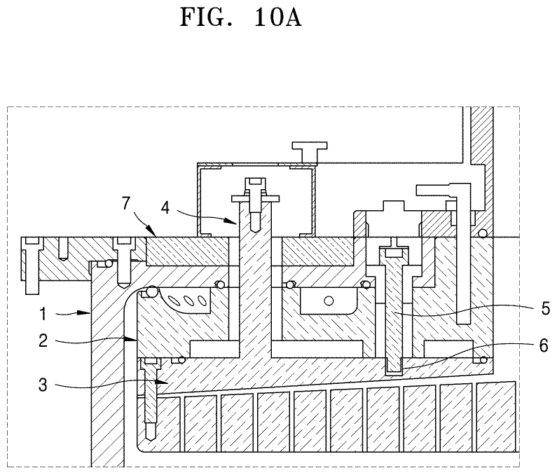

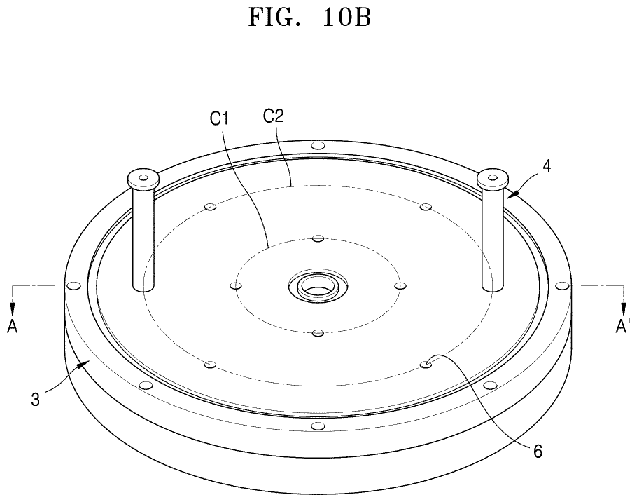

In more detail, a power supply portion such as an external plasma generator (not shown) may be electrically connected to a conductive protrusion 313 (of FIG. 3), and thus, the power (e.g., RF power) generated by the power supply portion may be transmitted to the processing unit 109 by the conductive protrusion 313 that functions as an RF rod. The conductive protrusion 313 may extend from the conductive body 323 of the processing unit 109 to the outside of a heating unit 7 (of FIG. 10A). Further, the conductive protrusion 313 may be formed to be integrated with the processing unit 109. Thus, there will be no mechanical coupling through a separate member between the conductive protrusion 313 and the conductive body 323 of the processing unit 109. As a result, the conductive protrusion 313 may extend from the conductive body 323 to the outside of the heating unit through an RF rod hole 303 (of FIG. 3) passing through an upper portion of the gas flow control unit 105 and the partition 101.

Optionally, the processing unit 109 is formed of a conductor, while the gas flow control unit 105 includes an insulating material such as ceramics, so that the gas supply unit 109 used as a plasma electrode may be insulated from the partition 101.

As shown in FIG. 1, a gas inlet 113 may be formed on the partition 101 to penetrate the partition 101 and penetrate the center of the gas flow control unit 105. In addition, a gas flow path 119 is further formed in the processing unit 109, and thus a reaction gas supplied through the gas inlet 113 from an external gas supply portion (not shown) may be uniformly supplied to each of gas injection holes 133 of the processing unit 109.

In addition, as shown in FIG. 1, a gas outlet 115 is arranged at an upper end of the partition 101 and asymmetrically arranged with respect to the gas inlet 113. Although not shown in the drawings, the gas outlet 115 may be disposed symmetrically with respect to the gas inlet 113. In addition, the partition 101 and a side wall of the gas flow control unit 105 (and a side wall of the processing unit 109) are apart from each other, and thus the gas exhaust path 117 through which a residual gas of the reaction gas is exhausted may be formed after the process proceeds.

FIG. 2 is a view showing a flow of a reaction gas (and residual gas) in the substrate processing apparatus 100 according to the disclosure. The arrow shows the direction of gas flow, and a reaction gas supplied from an external gas supply portion (not shown) to the gas inlet 113 may be uniformly supplied to a gas injection hole 133 formed inside the processing unit 109 through the gas flow path 119.

A chemical reaction of the reaction gas is performed in the reaction space 125 or on a substrate 110 to form a thin film on the substrate 110. After the thin film is formed, the residual gas, via the gas exhaust path 117 formed between the partition 101 and a side wall of the processing unit 109, flows into an inner space of the gas flow control unit 105 through the through holes 111 formed in the side wall 123 of the gas flow control unit 105, and then exhausted through the gas outlet 115 to the outside.

FIG. 3 is a cross-sectional view of the substrate processing apparatus 100 according to the disclosure as viewed from another section. Referring to FIG. 3, the gas flow control unit 105 includes the side wall 123, the gas inlet 113, a plate 301 surrounded by the side wall 123, an RF rod hole 303, a first coupling hole 305, a second coupling hole (not shown), a through hole 111, and a groove 127 for receiving a sealing member such as an O-ring. The plate 301 may be surrounded by the protruding side wall 123 and may have a concave shape.

The RF rod hole 303 may be provided on a portion (e.g., edge portion) of the gas flow control unit 105. Through the RF rod hole 303, the conductive protrusion 313 extending from the conductive body 323 of the processing unit 109 may be connected to an external plasma supply portion (not shown).

The processing unit 109 below the gas flow control unit 105 may act as an electrode in a plasma process of a CCP method. In this case, a gas supplied through a gas channel 323a (of FIG. 4) and a gas injection unit 323b (of FIG. 4) of the processing unit 109 will be activated by the processing unit 109 serving as an electrode and injected onto a substrate on the substrate support plate 103. The processing unit 109 may include the conductive protrusion 313 and the conductive body 323 integrated with the conductive protrusion 313.

In another portion (e.g., central portion) of the gas flow control unit 105, the gas inlet 113, which is a path through which an external reactor gas is introduced, is arranged. At least two first coupling holes 305 may be provided around the gas inlet 113. In an embodiment, the first coupling holes 305 may be arranged along a first circumference apart from the center of the processing unit 109 to have a first radius (see C1 in FIG. 4).

A first coupling unit (e.g., a screw) configured to connect the gas flow control unit 105 of the processing unit 109 to the conductive body 323 may penetrate the first coupling hole 305. Therefore, the conductive body 323 of the processing unit 109 and the conductive protrusion 313 integrally formed with the conductive body 323 may be fixed to the partition 101 through a first coupling unit arranged in the first coupling hole 305.

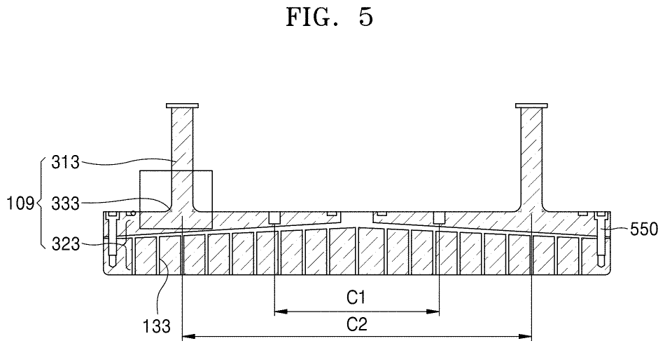

Although not illustrated in FIG. 3, at least two second coupling holes may be provided outside the first coupling hole 305. That is, the second coupling holes may be arranged along a second circumference apart from the center of the processing unit 109 to have a second radius greater than the first radius (see C2 in FIG. 4). Since the shape of the second coupling holes is more specifically shown in FIGS. 4 and 5, it will be described later using these.

In some embodiments, a heating unit 7 (of FIG. 10A) arranged to contact a partition may include a plurality of thermocouples. For example, a first thermocouple configured to measure the temperature of a first portion of a heating unit and a second thermocouple configured to measure the temperature of a second portion of the heating unit may be on the heating unit. The first thermocouple and the second thermocouple may be arranged symmetrically with respect to the center of the heating unit.

FIG. 4 is a view of a processing unit included in a substrate processing apparatus according to embodiments of the inventive concept. FIG. 5 is a cross-sectional view of the processing unit taken along line X-X′ in FIG. 4. The processing unit (e.g., a gas supply unit) of FIGS. 4 and 5 may be the processing unit of the substrate processing apparatus according to the above-described embodiments. Hereinafter, repeated descriptions of the embodiments will not be given herein.

Referring to FIGS. 4 and 5, the processing unit 109 may be configured to perform an appropriate function according to the function of the substrate processing apparatus. In an example, the processing unit 109 may perform an electrode function for applying plasma power. In another example, the processing unit 109 may perform a gas supply function configured to supply a gas. In another example, the processing unit 109 may be configured to perform both a power supply function and a gas supply function.

Hereinafter, it is assumed that the processing unit 109 is a gas supply unit configured to perform both a power supply function and a gas supply function.

The substrate processing apparatus may be a deposition (etching) apparatus for performing a deposition (etching) function, and may use plasma to promote reaction. In this case, the gas supply unit may be formed of a conductive member to perform as an electrode to apply the plasma thereto. For example, the gas supply unit may include the conductive body 323 and the conductive protrusion 313 that protrudes from the conductive body 323. Furthermore, the gas supply unit may include a plurality of gas inlets for gas supply. Gas for deposition (etching) may be supplied through the plurality of gas inlets of the gas supply unit.

The gas supply unit may include the conductive body 323 and the conductive protrusion 313. The conductive body 323 may include a gas injection portion 323b having the plurality of gas injection holes 133 and a gas channel 323a stacked on the gas injection portion 323b. The gas injection unit 323b and the gas channel 323a may be integrated and implemented as a single body, or may be implemented as separate parts. FIG. 5 shows a case where the gas channel 323a and the gas injection unit 323b are separately implemented, wherein the gas channel 323a and the gas injection unit 323b may be coupled to each other through a coupler 550 such as a screw.

The conductive protrusion 313 may extend to protrude from the conductive body 323. In an embodiment, the conductive protrusion 313 may be integrally formed with the conductive body 323. For example, the conductive body 323 and the conductive protrusion 313 may be integrally manufactured by a welding process such as welding, brazing, and soldering and/or a metal milling process. There will be no separate interface between the conductive body 323 and the conductive protrusion 313 because they are integrally manufactured in this way.

A metal conductive joint 333 may be formed between the conductive body 323 and the conductive protrusion 313. The metal conductive joint 333 may be formed as a result of the above-described welding process and/or milling process. Therefore, the conductive body 323, the conductive protrusion 313, and the metal conductive joint 333 may be integrally formed with each other.

In an embodiment, the metal conductive joint 333 may be formed to have a certain curvature. For example, as shown in FIGS. 3 and 5, the metal conductive joint 333 may be formed to have a concave shape. In more detail, an upper surface of the metal conductive joint 333 (the surface connecting the conductive body 323 and the conductive protrusion 313) may be concave. The concave surface may have a certain curvature. In another example, the metal conductive joint 333 may be formed to have a convex shape, and the convex shape may have a certain curvature.

In some embodiments, the metal conductive joint 333 may be implemented as a weld joint between the conductive body 323 and the conductive protrusion 313. That is, the metal conductive joint 333 is arranged between the conductive body 323 and the conductive protrusion 313 and the welding process is performed, so that the conductive body 323 and the conductive protrusion 313 may be integrated with each other. In another embodiment, the metal conductive joint 333 may be implemented as a milling joint between the conductive body 323 and the conductive protrusion 313. The milling joint may be formed by performing a metal milling process on an integrated metal body.

In some embodiments, the weld joint may include concave fillet weld formed by welding. An upper surface of such fillet weld may be concave. The concave fillet may be between the conductive body 323 and the conductive protrusion 313. Although the above description was made on the premise that the concave fillet is formed using welding, it is noted that the concave fillet may be formed using a process other than welding (e.g., a metal milling process). Therefore, the conductive body 323, the conductive protrusion 313, and the concave fillet may be integrally formed with each other by metal milling, or by metal joining, such as welding, brazing, and soldering.

The conductive body 323 of the processing unit 109 may include the gas injection portion 323b and the gas channel 323a. The gas injection portion 323b and the gas channel 323a may be integrally formed, or may be configured as a separate type in which the gas injection unit 323b having the gas injection holes 133 and the gas channel 323a stacked on the gas injection portion 323b are separated. The embodiments of FIGS. 4 and 5 show the conductive body 323 based on the embodiment in which the gas injection portion 323b and the gas channel 323a are configured as a separate type.

Referring to FIGS. 4 and 5, the conductive body 323 including the gas injection unit 323b and the gas channel 323a may include a first surface and a second surface opposite to the first surface. The first surface may correspond to a lower surface of the gas injection unit 323b, and the second surface may correspond to an upper surface of the gas channel 323a. A plurality of injection holes may be formed on the first surface, and a first coupling hole and a second coupling hole may be formed on the second surface.

The conductive protrusion 313 may be formed to protrude from the second surface that is the upper surface of the gas channel 323a. When the processing unit 109 is fixed to the partition 101 (of FIG. 3) of the substrate processing apparatus through the first coupling hole and the second coupling hole, one end of the conductive protrusion 313 protruding from the second surface may be extended to pass through the partition 101 (of FIG. 3) of the substrate processing apparatus. Therefore, an end of the conductive protrusion 313 extending out of the partition 101 (of FIG. 3) may be electrically connected to a power supply portion (not shown).

A second coupling unit (e.g., a screw) configured to connect the gas flow control unit 105 and the processing unit 109 may penetrate the second coupling hole. Therefore, the conductive body 323 of the processing unit 109 and the conductive protrusion 313 integrally formed with the conductive body 323 may be additionally fixed to the partition 101 through the second coupling unit arranged in the second coupling hole.

In some embodiments, the conductive protrusion 313 may protrude on a second circumference C2 having a second radius greater than a first radius of a first circumference C1. That is, in one cross-section, the conductive protrusion 313 may be apart from the center of the processing unit 109 by the second radius, and in another cross-section, the second coupling hole may also be apart from the center of the processing unit 109 by the second radius.

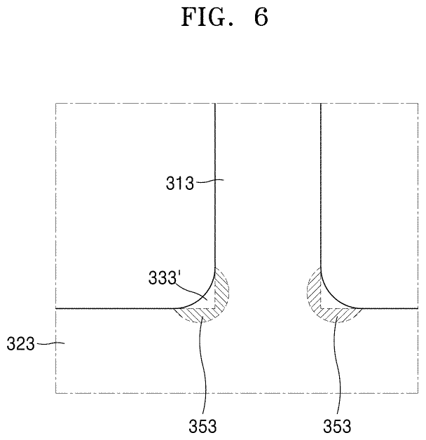

FIG. 6 is a partial view of a processing unit included in a substrate processing apparatus according to embodiments of the inventive concept. The processing unit (e.g., a gas supply unit) of FIG. 6 may be the processing unit of the substrate processing apparatus according to the above-described embodiments. Hereinafter, repeated descriptions of the embodiments will not be given herein.

Referring to FIG. 6, the conductive body 323 and the conductive protrusion 313 of the processing unit may be formed of a single structure using a weld joint 333′. That is, after the conductive body 323 and the conductive protrusion 313 are individually formed, a fillet weld is arranged between the conductive body 323 and the conductive protrusion 313 and a welding process is performed, so that the conductive body 323, the conductive protrusion 313, and the weld joint 333′ may be integrated. In this case, at least one of the conductive body 323, the conductive protrusion 313, and the weld joint 333′ may include a heat-affected portion 353. The heat-affected portion 353 is formed during a welding process, and may have properties different from those of the conductive body 323, the conductive protrusion 313, and the weld joint 333′.

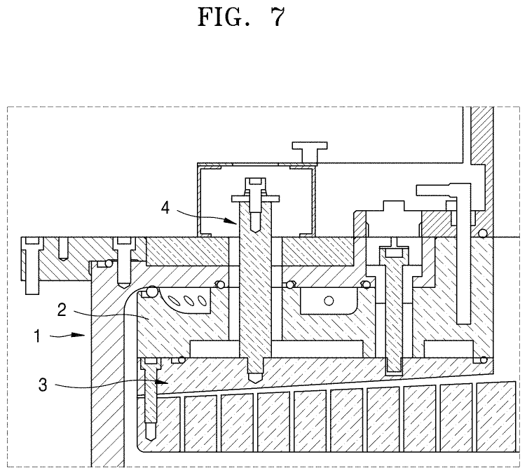

FIG. 7 shows an embodiment where a gas curtain 3, which is a conductive body of a processing unit, and an RF rod 4, which is a conductive protrusion, are not integrated with each other and are mechanically coupled as separate components.

Referring to FIG. 7, the gas curtain 3 in direct contact with a reaction space is fixed to a reactor wall 1 and a gas flow control ring 2 by a plurality of connection devices penetrating through a central portion of the reactor wall 1, such as screws. The gas curtain 3 includes a conductive material to transmit RF power to a gas injection device coupled to the bottom, such as a showerhead. The gas flow control ring 2 provides an exhaust path with through holes formed in a protruding side wall, and includes an insulating material for RF insulation between the reactor wall 1 and the gas curtain 3.

A plurality of RF rods 4 that transmit RF power in a reactor are arranged symmetrically with respect to the center of the gas curtain 3 and are connected to the gas curtain 3. That is, in order to uniformly supply RF power to the reaction space, the plurality of RF rods 4 penetrate the reactor wall 1 and the gas flow control ring 2 symmetrically with respect to the center of the reactor wall 1 and the gas flow control ring 2 and are inserted into the gas curtain 3. A connection portion of the RF rod 4 for insertion has a screw shape in one embodiment, and the connection portion of the screw shape is inserted into a groove formed in the gas curtain 3. The insertion of the RF rod 4 may be done by manual assembly. However, as the reactor wall 1 and the gas curtain 3 are deformed at a high temperature, a coupling force between the RF rod 4 and the gas curtain 3 may be weakened, or the RF rod 4 may be detached from the gas curtain 3, resulting in deformation and cracking. In this case, the regulated RF power supply is not performed, resulting in RF power loss.

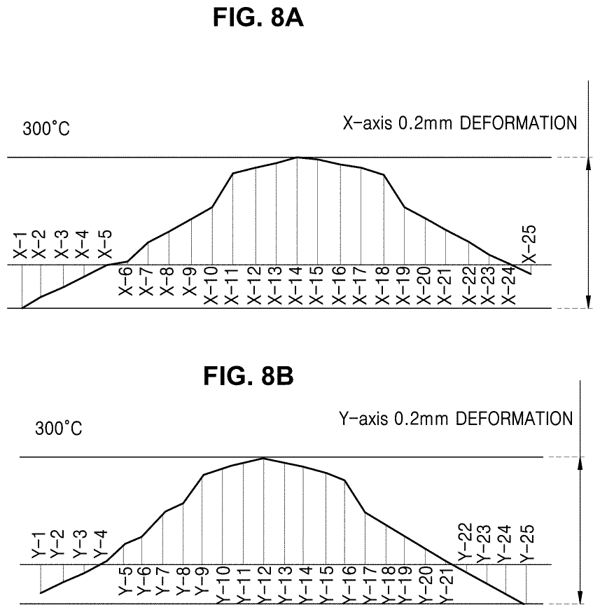

FIG. 8 shows deformation of the gas curtain 3. In particular, the degree to which the gas curtain 3 is deformed at a high temperature, such as a process temperature of 300° C., is shown in FIG. 8. FIG. 8A shows the degree of deformation in an X-axis direction, and FIG. 8B shows the degree of deformation in a Y-axis direction.

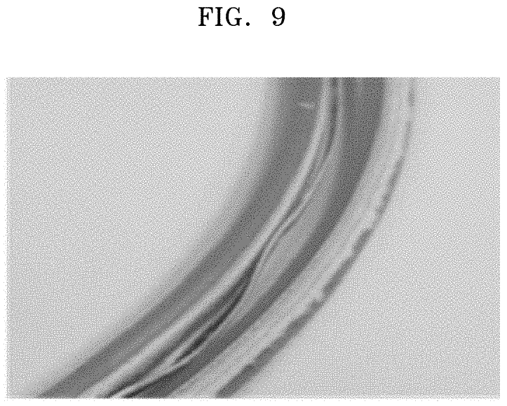

A central portion of a graph shown in FIG. 8 represents a central portion of the gas curtain 3, and both ends represent a peripheral portion of the gas curtain. That is, it can be seen that the peripheral portion of the gas curtain 3 sags downward compared to the center portion, and the degrees of deformation in the X and Y axis directions are similar to each other. As the peripheral portion of the gas curtain 3 sags, a gap is created between the peripheral portion of the gas curtain 3 and the gas flow control ring 2, and the gas curtain 3 is exposed to a cleaning gas (e.g., NF3) exhausted through an exhaust path formed between the reactor wall 1, the gas flow control ring 2 and the gas curtain 3, and thus a sealing device disposed between the gas flow control ring 2 and the gas curtain 3, such as an O-ring, is corroded and the cleaning gas remains as an impurity in a reaction space (see FIG. 9). Alternatively, a gas exhausted during the process flows into and remains through the gap, and acts as an impurity in the process.

FIGS. 10A and 10B are views of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIGS. 10A and 10B, the RF rod 4 is coupled to the gas curtain 3 in one-body. For example, the RF rod 4 and the gas curtain 3 may be coupled by welding, thereby strengthening the coupling between the RF rod 4 and the gas curtain 3 to prevent leakage of RF power even in a high temperature process. In addition, the reactor wall 1 and the gas curtain 3 may be coupled to each other by a connection device 5, such as a screw. The connection device 5 penetrates the reactor wall 1 and the gas flow control ring 2 and is coupled to the gas curtain 3. A plurality of connection holes 6 are provided on one surface of the gas curtain 3, and the connection device 5 is coupled to the gas curtain 3 through a connection hole 6. In the existing gas curtain 3 (of FIG. 7), connection holes are concentrated in the center of the gas curtain 3. In the gas curtain 3 according to the disclosure, however, the connection holes 6 (of FIG. 10B) are formed not only in the center of the gas curtain 3 but also in the periphery, thereby strengthening the coupling between the reactor wall 1 and the gas curtain 3 and preventing the gas curtain 2 from being deformed even at a high temperature.

FIG. 10A shows the cross section of a reactor as seen along line A-A′ in FIG. 10B, showing that two RF rods 4 and two connection devices 5 are coupled to the gas curtain 3. As can be seen from FIGS. 10A and 10B, for uniform supply of RF power to the gas curtain 3, the RF rods 4 are symmetrically arranged with respect to the center of the gas curtain 3, and the connection holes 6 are also arranged symmetrically with respect to the center of the gas curtain 3 for a uniform coupling force between the reactor wall 1 and the gas curtain 3. In FIGS. 10A and 10B, two RF rods 4, eight connection devices 5, and eight connection holes 6 are arranged, but the number is not limited thereto.

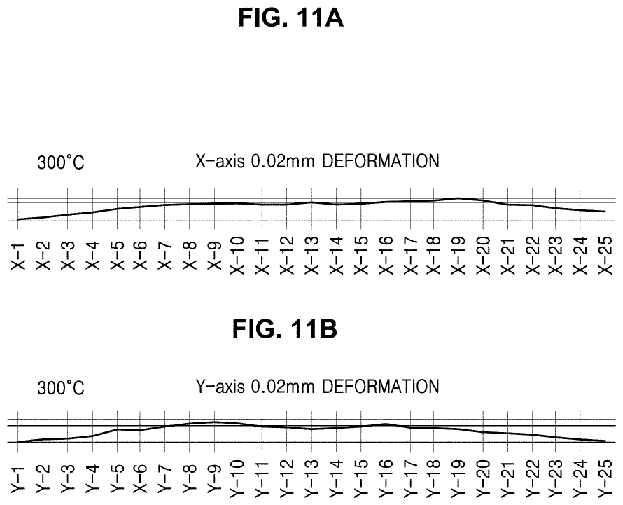

FIG. 11 shows the degree of deformation and process results of a reactor at a high temperature when a plurality of connection devices 5 and connection holes 6 are applied to the center and periphery of the gas curtain 3 according to FIG. 10.

As shown in FIG. 11, in a reactor according to the disclosure, it can be seen that deformation of a peripheral portion of a gas curtain at a high temperature is significantly lower than that shown in FIG. 8. That is, in the reactor according to the disclosure, by adding additional connection devices to the peripheral portion of the gas curtain, there is a technical effect that may suppress physical deformation of the gas curtain.

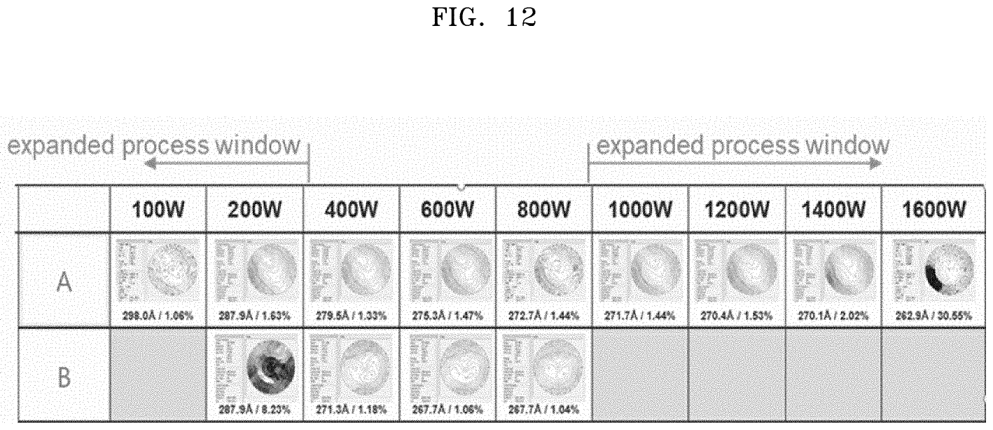

FIG. 12 shows process results in the processing apparatus (FIG. 7) using a separate and inserted RF rod, and the processing device (FIG. 10) in which an RF rod and a gas curtain are integrated according to the disclosure. In the process, a SiO2 film is deposited using a plasma atomic layer process at a process temperature of 300° C.

A lower portion (portion B) of FIG. 12 shows process results in a structure in which a separate RF rod is inserted into a gas curtain, and an upper portion (portion A) of FIG. 12 shows process results in a structure in which an RF rod and a gas curtain are integral as in FIG. 7. As shown in FIG. 12, it can be seen that a process window is significantly greater in a reactor of the structure in which the RF rod and the gas curtain are integrated, than in a reactor of a separate structure. That is, it can be seen that a stable process is possible at a greater range of RF power in the integrated structure. It can be seen that RF power dissipation is greatly reduced by maintaining coupling between the RF rod and the gas curtain in the integral structure.

In more detail, according to FIG. 12, in a reactor having a separation type processing device, when RF power is 200 watts or less and 1000 watts or more, thin film deposition is not performed on a substrate. However, in a reactor with an integrally structured processing apparatus according to the embodiments of the inventive concept, it can be seen that a RF power range for stable process has been extended to the range of 100-1600 watts. Therefore, the disclosure has a technical effect to prevent process defects and process reproducibility degradation due to manual assembly in the existing reactor.

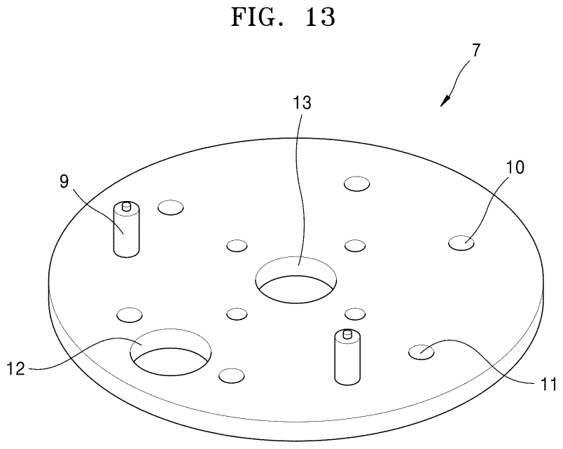

As an additional process variable affecting a high temperature process, in addition to the above described physical connection structure between the reactor wall and the gas curtain and the physical connection structure between the RF rod and the gas curtain, uniform temperature distribution in the reactor wall is also important. Non-uniform temperature distribution on the surface of the reactor wall may cause cold spots and degrade process reproducibility. FIG. 13 shows a thermocouple (TC) measuring the temperature and a wall heater on a partition, introduced to solve this problem.

Referring to FIG. 13, a reactor wall heater 7 includes a material containing a heating element. When a TC (thermocouple) 9 for measuring a temperature of a reactor wall heater of a reactor is arranged only on one side of the reactor wall heater 7, temperature distribution of the reactor wall heater and the top of a reactor wall may not be uniform. Therefore, in the disclosure, a plurality of thermocouples are arranged for more uniform temperature measurement and heating. The thermocouples are arranged to face each other and more preferably to be symmetrical with respect to the center of the reactor wall heater. In addition, in order to prevent the occurrence of a cold spot having a relatively low temperature at the top of the reactor wall, the reactor wall heater 7 opens only a path through which an RF rod, a gas curtain connection device, an exhaust port, and a gas inlet pass. In more detail, the reactor wall heater 7 is provided with two thermocouples 9, eight screw holes 10, and two RF rod holes 11, and a gas inlet hole 13 in the center. A reactor wall heater 8 is arranged in the other areas so that a cold spot is not generated on the top of a lower reactor wall.

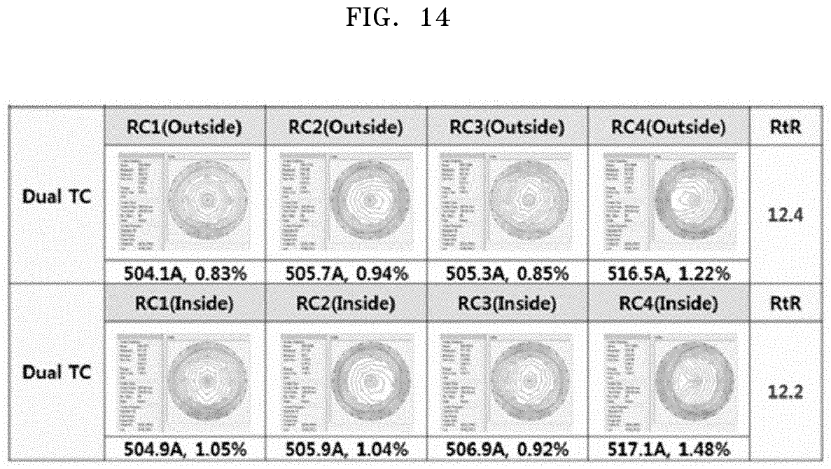

FIG. 14 shows process results when a dual TC is applied.

Referring to FIG. 14, when a dual TC is applied to a multi-chamber system with four reactors R1, R2, R3, and R4, in the reactors R1, R2, R3 and R4, the thickness deviation of a thin film between the inside and outside of substrate is less than or equal to the reference value of 2.0 Å, and the thickness deviation of a thin film between the reactors is less than or equal to the reference value of 13 Å. Therefore, it can be seen that, by implementing the dual TC, in a substrate and among reactors, allowable deviation of process reproducibility is achieved.

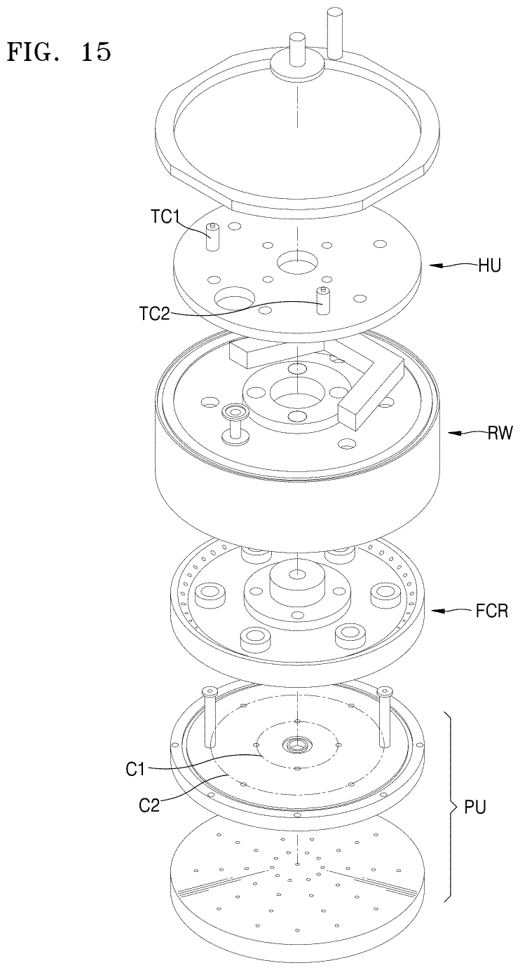

FIG. 15 is a view of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 15, as a reactor structure, the above-described integral RF rod, the plurality of connection devices (FIG. 10), and the reactor wall heater (FIG. 13) are applied. A conductive protrusion, which is the integral RF rod, is formed to extend from a conductive body that is a gas curtain, and the plurality of connection devices (not shown) may be configured to fix a processing unit PU to a partition RW. In this case, a flow control ring FCR may be disposed between the processing unit PU and the partition RW, so that the processing unit PU and the flow control ring FCR may be fixed to the partition RW by a connection device.

The connection device may include a first coupling unit arranged along the first circumference C1 and a second coupling unit arranged along the second circumference C2. Therefore, a fixing force of the processing unit PU to the partition RW achieved by the first coupling unit arranged along the first circumference C1 may be strengthened by the second coupling unit arranged along the second circumference C2. As a result, sagging of the processing unit PU occurring at a high temperature may be prevented.

Furthermore, a heating unit HU is arranged to contact the partition RW, and the temperature of the heating unit HU is measured by a plurality of thermocouples TC1 and TC2. Through these configurations, it is possible to minimize deformation of a reactor and prevent loss of RF power during a plasma process at a high temperature. In addition, it is possible to achieve process reproducibility within a substrate and process reproducibility among reactors, by uniformizing temperature distribution at the top of a reactor wall.

It is to be understood that the shape of each portion of the accompanying drawings is illustrative for a clear understanding of the disclosure. It should be noted that the portions may be modified into various shapes other than the shapes shown.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a partition; and
a processing unit below the partition,
wherein the processing unit comprises:
a conductive body; and
at least one conductive protrusion formed integrally with the conductive body.

2. The substrate processing apparatus of claim 1, further comprising a conductive joint between the conductive body and the conductive protrusion,
wherein the conductive body, the conductive protrusion, and the conductive joint are integrally formed.

3. The substrate processing apparatus of claim 2, wherein the conductive joint has a curvature.

4. The substrate processing apparatus of claim 2, wherein the conductive joint has a concave shape.

5. The substrate processing apparatus of claim 1, further comprising a weld joint between the conductive body and the conductive protrusion.

6. The substrate processing apparatus of claim 5, wherein the weld joint comprises a fillet weld.

7. The substrate processing apparatus of claim 6, wherein the fillet weld has a concave shape.

8. The substrate processing apparatus of claim 5,
wherein at least one of the conductive body, the conductive protrusion, and the weld joint further comprises a heat-affected portion, and
the heat-affected portion has properties different from those of the conductive body, the conductive protrusion, and the weld joint.

9. The substrate processing apparatus of claim 1, wherein the conductive body comprises:
a plurality of first coupling holes formed along a first circumference apart from the center of the conductive body and having a first radius; and
a plurality of second coupling holes formed along a second circumference apart from the center of the conductive body and having a second radius greater than the first radius.

10. The substrate processing apparatus of claim 9, wherein the conductive body and the conductive protrusion are fixed to the partition through a first coupling unit arranged in the first coupling holes, and
the conductive body and the conductive protrusion are further fixed to the partition through a second coupling unit arranged in the second coupling holes.

11. The substrate processing apparatus of claim 9, wherein the at least one conductive protrusion is on the second circumference.

12. The substrate processing apparatus of claim 1, wherein the conductive body comprises a first surface in which a plurality of injection holes are formed and a second surface opposite to the first surface, and
the conductive protrusion protrudes from the second surface.

13. The substrate processing apparatus of claim 12, wherein the conductive protrusion comprises an end portion extending from the second surface to pass through the partition.

14. The substrate processing apparatus of claim 13, wherein the substrate processing apparatus further comprises a power supply portion, and
the end portion of the conductive protrusion is electrically connected to the power supply portion.

15. The substrate processing apparatus of claim 1, further comprising:
a heating unit arranged to contact the partition;
a first thermocouple configured to measure a temperature of a first portion of the heating unit; and
a second thermocouple configured to measure a temperature of a second portion of the heating unit.

16. The substrate processing apparatus of claim 15, wherein the first thermocouple and the second thermocouple are arranged symmetrically with respect to the center of the heating unit.

17. A gas supply unit comprising:
a conductive body;
a conductive protrusion protruding from the conductive body; and
a concave fillet between the conductive body and the conductive protrusion.

18. The gas supply unit of claim 17, wherein the conductive body, the conductive protrusion, and the concave fillet are integrally formed with each other by metal milling.

19. The gas supply unit of claim 17, wherein the conductive body, the conductive protrusion, and the concave fillet are integrally formed with each other by metal joining.

20. A substrate processing apparatus comprising:
a partition;
a heating unit in contact with the partition;
a plurality of thermocouples configured to measure a temperature of the heating unit;
a processing unit having a conductive body and at least one conductive protrusion integrally formed with the conductive body;
a plurality of first coupling units configured to fix the processing unit to the partition; and
a plurality of second coupling units configured to fix the processing unit to the partition,
wherein the first coupling unit is arranged along a first circumference, and the second coupling unit is arranged along a second circumference having a greater diameter than that of the first circumference, and
a fixing force of the processing unit to the partition generated by the first coupling unit arranged along the first circumference is increased by the second coupling unit arranged along the second circumference.
